(19) United States
(12) Patent Application Publication
(10) Pub. No.: US 2009/0235984 A1
(43) Pub. Date: Sep. 24, 2009

(54) Solar cell module

(75) Inventors: Hwa-Yuh Shin, Longtan Shiang (TW); Yam-Mou Shyu, Longtan (TW); Hung-Zen Kuo, Longtan Shiang (TW); Chun-Yi Chen, Longtan Shiang (TW)

Correspondence Address: TROXELL LAW OFFICE PLLC;SUITE 1404, 5205 LEESBURG PIKE, FALLS CHURCH, VA, 22041, US

(73) Assignee: ATOMIC ENERGY COUNCIL - INSTITUTE OF NUCLEAR ENERGY RESEARCH, Taoyuan (TW)

(21) Appl. No.: 12/076,709

(22) Filed: Mar. 21, 2008

(51) Int. Cl. H01L 31/0232

(52) U.S. Cl. 136/259

(57) ABSTRACT

A solar cell module includes a solar cell, a ring and a lens. The solar cell includes at least one photo detector provided on the top, a plurality of pins extended from the bottom and at least a mark formed thereon for marking the pins. The ring is detachably mounted on the solar cell. The ring includes an upper window and a lower window. The lens is disposed in the ring for closing at least one of the upper and lower windows.

### FIELD OF THE INVENTION

The present invention relates to a solar cell module and, more particularly, to a solar cell module for proper operation under various conditions.

### DESCRIPTION OF THE RELATED ARTS

Referring to FIG. 8, a conventional solar cell module includes a circuit board 6, a plurality of solar cells 7 fixed on the circuit board 6 by soldering, and a lens 8 for focusing sunlit onto the solar cells 7. The solar cells 7 convert the focused sunlit into electricity. However, each of the solar cells 7 converts sunlit into electricity at different efficiencies in different seasons. Moreover, solar cells 7 in different positions of the circuit board 6 convert sunlit into electricity at different efficiencies. The single lens 8 cannot effectively focus sunlit onto the solar cells 7 so that the solar cells 7 cannot efficiently convert the focused sunlit into electricity.

The present invention is therefore intended to obviate or at least alleviate the problems encountered in prior art.

### SUMMARY OF THE INVENTION

It is the primary objective of the present invention to provide a solar cell module for proper operation under various conditions.

To achieve the foregoing objective, the solar cell module includes a solar cell, a ring and a lens. The solar cell includes at least one photo detector provided on the top, a plurality of pins extended from the bottom and at least a mark formed thereon for marking the pins. The ring, with an upper window and a lower window, is detachably mounted on the solar cell. The lens is disposed in the ring for closing at least one of the upper and lower windows.

Other objectives, advantages and features of the present invention will become apparent from the following description referring to the attached drawings.

### BRIEF DESCRIPTION OF THE DRAWINGS

The present invention will be described via the detailed illustration of the preferred embodiment referring to the drawings.

FIG. 1 is a perspective view of a solar cell module according to the preferred embodiment of the present invention.

FIG. 2 is an exploded view of the solar cell module shown in FIG. 1.

FIG. 3 is a top view of the solar cell module shown in FIG. 1.

FIG. 4 is a cross-sectional view of the solar cell module shown in FIG. 1.

FIG. 5 is a cross-sectional view of the solar cell module shown in FIG. 1 in operation under the sun.

FIG. 6 is an exploded view of the solar cell module in FIG. 1 which shows how to replace the original cell with a new one

FIG. 7 is an exploded view of the solar cell module shown in FIG. 1 when a original lens and a original ring are replaced with new ones.

FIG. 8 is a side view of a conventional solar cell module.

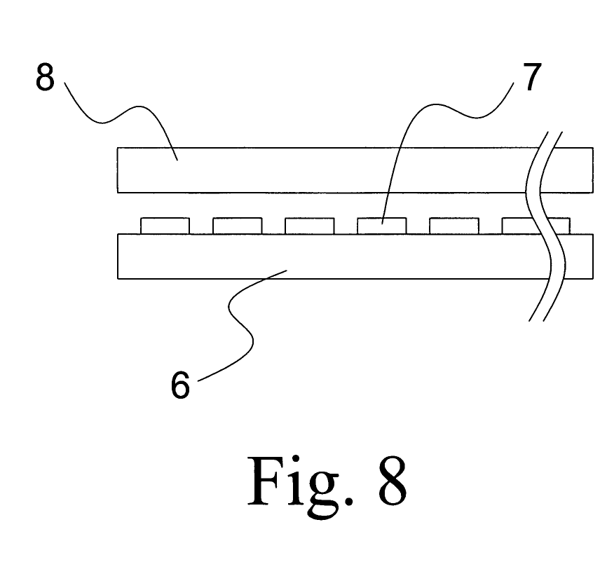

### DETAILED DESCRIPTION OF EMBODIMENT

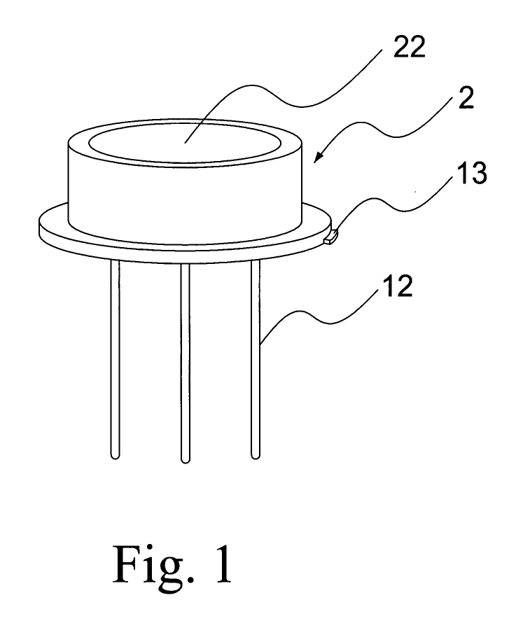

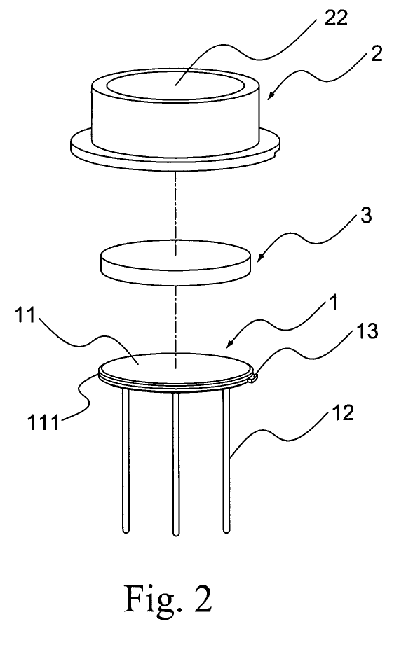

Referring to FIG. 1, there is shown a solar cell module according to the preferred embodiment of the present invention. The solar cell module includes a solar cell 1, a ring 2 and a lens 3. The solar cell 1 can be combined with the ring 2 so that the lens 3 is provided over the solar cell 1. Referring to FIGS. 2, 6 and 7, the solar cell 1 can be disengaged from the ring 2 so that the lens 3 can be replaced with another lens when the working conditions change for the solar cell module.

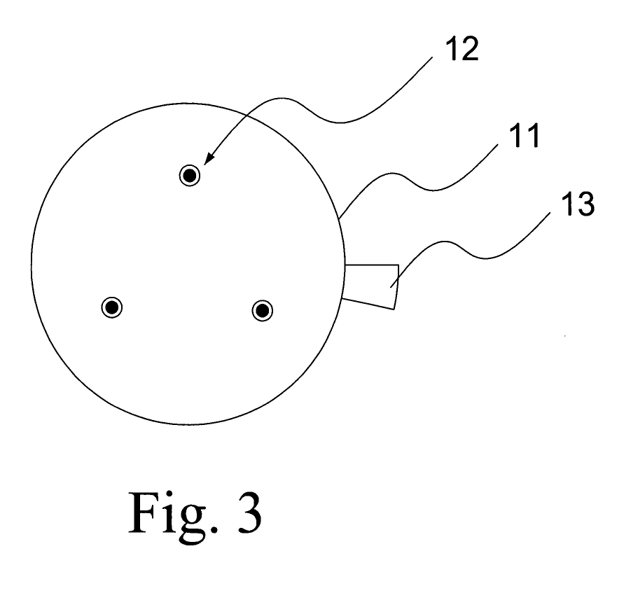

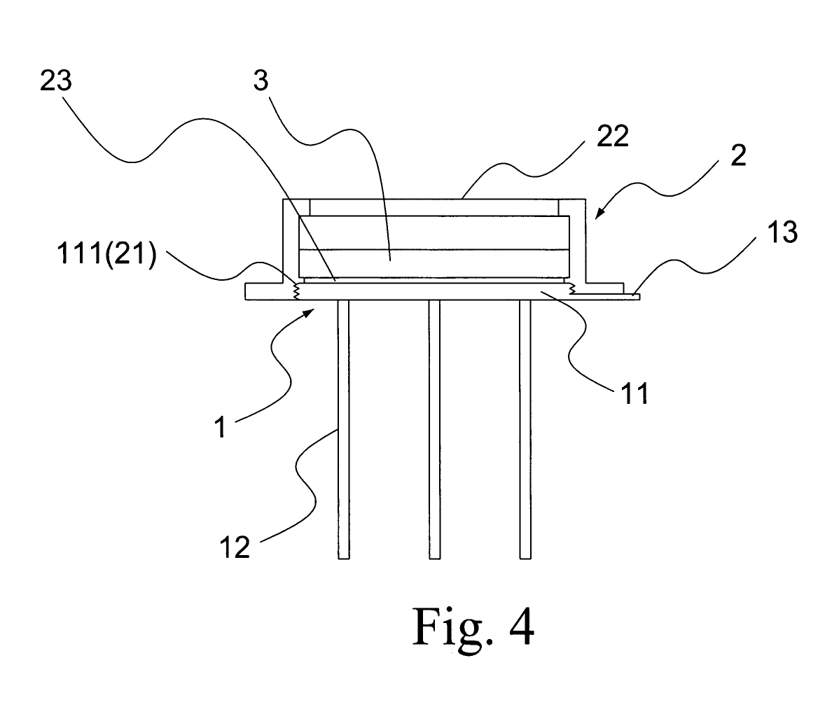

Referring to FIGS. 2 through 4, the solar cell 1 preferably includes three photo detectors 11 three pins 12 each extended from a related one of the photo detectors 11, a mark 13 formed thereon and a thread 111 formed thereon. The mark 13 may preferably be a tab formed on the periphery of the solar cell 1 or a unique area on the solar cell 11. The thread 111 is preferably formed along the periphery of solar cell 1.

The ring 2 is detachably mounted on the solar cell 1. The ring 2 includes an upper internal annular flange and a lower internal annular flange. An upper window 22 is defined by the upper internal annular flange. A lower window 23 is defined by the lower internal annular flange. A thread 21 is formed along the lower internal annular flange.

The lens 3 is disposed in the ring 2 to close at least the upper window 22.

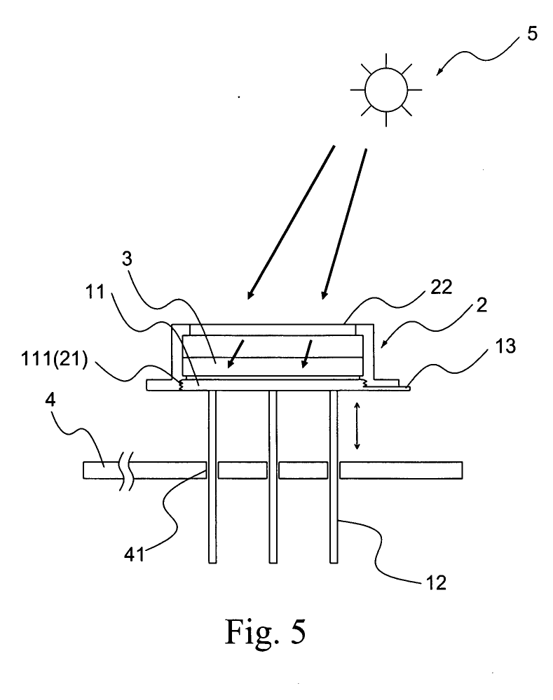

Referring to FIG. 5, the solar cell 1 is provided on a circuit board 4. The pins 12 are inserted in apertures 41 defined in the circuit board 4. The apertures 41 are of different electrodes. The mark 13 lets an assembling persona know the electrodes of the pins 12, thus avoiding the insertion of the pins 12 into wrong apertures 41.

The sun 5 casts sunlit onto the solar cell module. The lens 3 focuses the sunlit onto the photo detectors 11. The photo detectors 11 convert the focused sunlit into electricity.

Referring to FIGS. 2, 6 and 7, for some reasons, the lens 3 can be replaced with another lens after the solar cell 1 is disengaged from the ring 2.

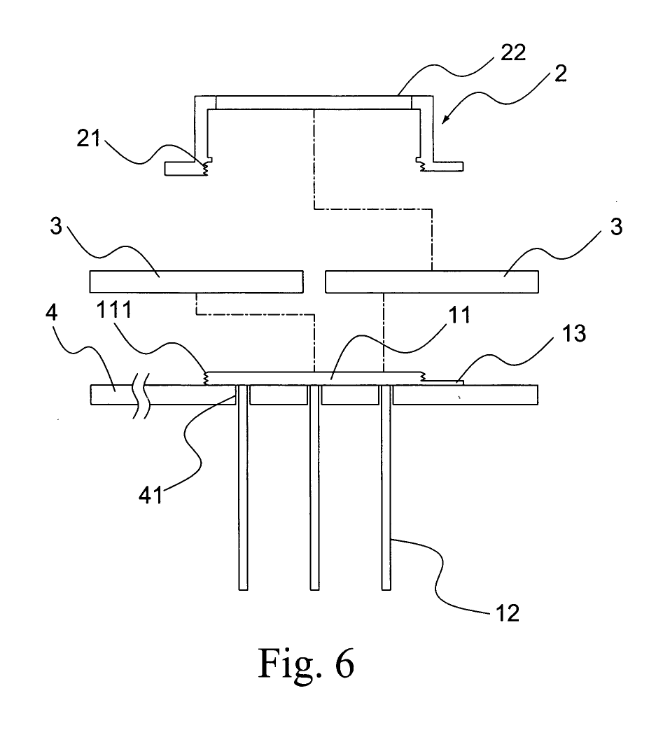

Referring to FIG. 6, ring 2 is disengaged from the solar cell 1 so that the lens 3 can be replaced with another one.

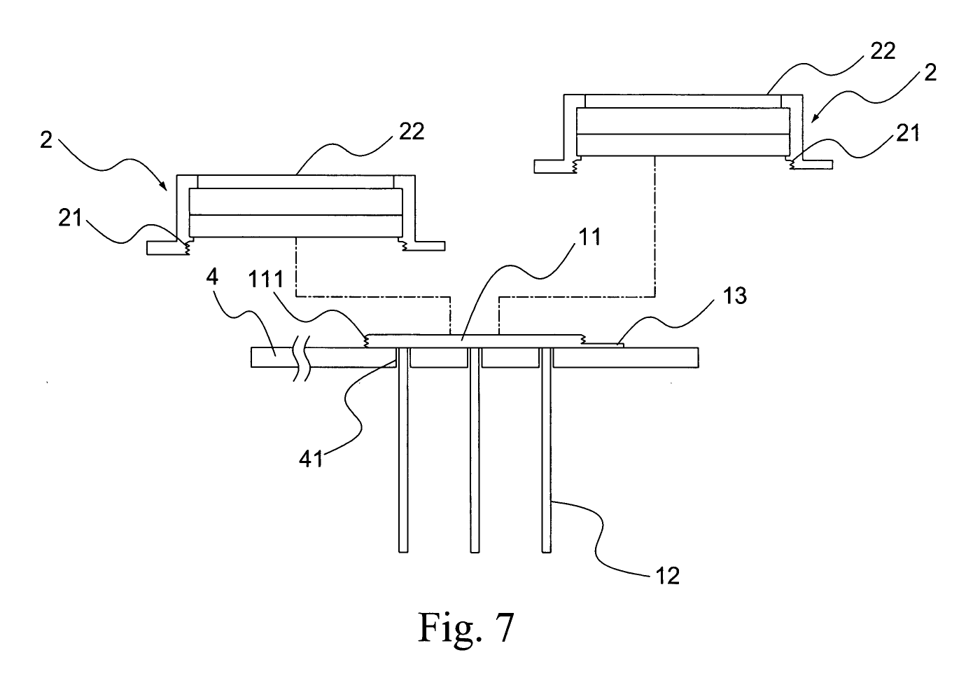

Referring to FIG. 7, the lens 3 is secured to the ring 2. The ring 2 and the lens 3 are disengaged from the solar cell 1 and replaced with another ring and another lens.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. A solar cell module comprising:
a solar cell comprising at least one photo detector provided on the top, a plurality of pins extended from the bottom and at least a mark formed thereon for marking the pins;
a ring detachably mounted on the solar cell, the ring comprising an upper window and a lower window; and
a lens disposed in the ring for closing at least one of the upper and lower windows.

2. The solar cell module according to claim 1, wherein the solar cell comprises a thread formed thereon, and the ring comprises a thread for engagement with the thread of the solar cell.

3. The solar cell module according to claim 2, wherein the thread of the solar cell is formed along the periphery of the solar cell.

4. The solar cell module according to claim 1, wherein the mark is a tab formed on the periphery of the solar cell.
